(19) United States
(12) Patent Application Publication
(10) Pub. No.: US 2026/0141140 A1
(43) Pub. Date: May 21, 2026

(54) METHOD AND APPARATUS FOR PREDICTING BATTERY THERMAL RUNAWAY USING ARTIFICIAL INTELLIGENCE

(71) Applicant: IUCF-HYU (INDUSTRY-UNIVERSITY COOPERATION FOUNDATION HANYANG UNIVERSITY), Seoul (KR)

(72) Inventors: Kiyong OH, Seoul (KR); Jinho JEONG, Seoul (KR)

(73) Assignee: IUCF-HYU (INDUSTRY-UNIVERSITY COOPERATION FOUNDATION HANYANG UNIVERSITY), Seoul (KR)

(21) Appl. No.: 19/396,746

(22) Filed: Nov. 21, 2025

(30) Foreign Application Priority Data
Nov. 21, 2024 (KR) 10-2024-0167135

(51) Int. Cl. G06F 30/27

(52) U.S. Cl. CPC G06F 30/27

(57) ABSTRACT

In a method performed by an electronic device using artificial intelligence according to an embodiment of the present disclosure, the method comprises a step of receiving audio data; a step of determining a plurality of first data representing a plurality of resolutions based on at least one of a sampling rate and a window size of the audio data; and a step of outputting second data from a pre-trained first artificial intelligence network using the plurality of first data as input information, wherein the pre-trained first artificial intelligence network may be trained based on the plurality of first data and third data output from a second artificial intelligence network. (FIG. 12)

### CROSS-REFERENCE TO RELATED APPLICATION

This application claims the benefit of Korean Patent Application No. 10-2024-0167135, filed on Nov. 21, 2024, in the Korean Intellectual Property Office, the disclosures of which are incorporated herein in its entirety by reference.

### BACKGROUND

### 1. Field

The present disclosure relates to a method and an apparatus for predicting thermal runaway of a battery using artificial intelligence.

### 2. Description of the Related Art

With the development of technologies such as electric vehicles, the use of batteries is increasing, and interest in battery stability is gradually growing. In relation to battery stability, various studies have been proposed to prevent battery thermal runaway (TR). Here, thermal runaway refers to a phenomenon where the temperature rises due to the use of a lithium-ion battery (LIB), causing ignition or explosion.

Since such thermal runaway may be prevented if predicted in advance, it is important to predict it quickly and accurately. However, since a rise in temperature does not immediately lead to thermal runaway, accurately predicting it requires considerable time and cost.

To solve this problem, a method for predicting and managing thermal runaway is proposed through a process of assuming various situations where thermal runaway may occur and training a deep learning model based thereon.

### SUMMARY

The present disclosure aims to provide an artificial intelligence model for predicting thermal runaway.

The present disclosure aims to provide a method for measuring the possibility of thermal runaway by predicting the state of a battery based on the temperature of the battery using artificial intelligence.

According to an embodiment of the present disclosure, a method performed by a thermal runaway prediction apparatus using artificial intelligence comprising: measuring a temperature at a specific location of a battery; outputting state information of the battery at a specific time point from a pre-trained artificial intelligence algorithm model by using the temperature at the specific location of the battery and a cooling performance as an input; and predicting a possibility of thermal runaway based on the state information of the battery.

According to an exemplary embodiment, the specific location of the battery comprises at least one of a surface of the battery and an interior of the battery.

According to an exemplary embodiment, the cooling performance comprises a performance of a cooling system applied to the battery, and the performance of the cooling system comprises a temperature, a velocity, a specific heat, and a forced convection coefficient of a cooling fluid applied to the battery.

According to an exemplary embodiment, the state information of the battery at the specific time point comprises a temperature of the battery, a concentration of a solid electrolyte interphase (SEI), a concentration of an anode, a concentration of a cathode, and a concentration of an electrolyte at the specific time point.

According to an exemplary embodiment, the predicting of the possibility of thermal runaway comprises: predicting the thermal runaway to occur when a temperature of the battery increases at a predetermined slope or more; or predicting the thermal runaway to occur when at least one of a concentration of the SEI, a concentration of the anode, a concentration of the cathode, and a concentration of the electrolyte becomes a predetermined value or more; or predicting the thermal runaway to occur at a time point when a reaction of the anode starts.

According to an exemplary embodiment, the pre-trained artificial intelligence algorithm model is configured as a single artificial intelligence model or is configured with two or more sub-models, the artificial intelligence model or the two or more sub-models each comprises a plurality of branch networks and a trunk network, and the artificial intelligence model or the two or more sub-models are pre-trained by using, as an input, the cooling performance, state information of the battery included in a virtual data set, a temperature of the battery, location information of the battery, a prediction time point, and domain information.

According to an exemplary embodiment, the virtual data set is generated through a multi-physics calculation model based on a virtual heating curve data set determined from a virtual scenario, the virtual heating curve data set is determined by a combination of an initial temperature, an initial time, a heating target temperature, and a heating time, and the multi-physics calculation model comprises a state estimation model, a thermodynamics model, a chemical reaction model, and a pressure estimation model related to an occurrence of thermal runaway of the battery.

According to an exemplary embodiment, the pre-trained artificial intelligence algorithm model is trained by a method in which: a first sub-model among the at least two or more sub-models outputs latent feature information by using, as an input, the cooling performance, the state information of the battery, the temperature of the battery, the location information of the battery, and the domain information, a second sub-model among the at least two or more sub-models outputs predicted state information of the battery by using, as an input, the cooling performance, the state information of the battery, the temperature of the battery, the location information of the battery, the prediction time point, and the latent feature information, and the training is performed based on a final loss determined based on the outputted predicted state information of the battery and the state information of the battery.

According to an exemplary embodiment, the final loss is determined based on loss items, the loss items comprise at least one of a data fitting loss, a physics loss, a boundary condition loss, and an initial condition loss, and each of the loss items is determined by applying an adaptive weight.

According to an exemplary embodiment, the domain information comprises a size of a domain window, a number of domains, measurement time information within the domain window, and time difference information between the domain and a prediction time point, and the latent feature information comprises a latent feature of a temperature, a concentration of an SEI, a concentration of an anode, a concentration of a cathode, and a concentration of an electrolyte at a specific location of the battery in a predetermined time domain.

According to an exemplary embodiment, the outputting of the state information of the battery comprises outputting the state information of the battery by utilizing the trained artificial intelligence algorithm model when the temperature at the specific location of the battery exceeds a threshold value.

According to an exemplary embodiment, the state information of the battery comprises gas composition of the battery and internal pressure information of the battery.

According to an exemplary embodiment, the method further comprises comparing the possibility of thermal runaway with a threshold value; and driving a system for controlling the thermal runaway when the possibility of thermal runaway is equal to or greater than the threshold value, and the system for controlling the thermal runaway comprises a cooling system and a phase transition system.

According to an embodiment of the present disclosure, an electronic device comprises a memory; a modem; and a processor connected to the modem and the memory, the processor is configured to: measure a temperature at a specific location of a battery, output state information of the battery at a specific time point from a pre-trained artificial intelligence algorithm model by using the temperature at the specific location of the battery and a cooling performance as an input, and predict a possibility of thermal runaway based on the state information of the battery.

As a program stored in a medium for predicting thermal runaway through an artificial intelligence algorithm executable by a processor according to an embodiment of the present disclosure, the program performs a step of measuring a temperature at a specific location of a battery; outputting state information of the battery at a specific time point from a pre-trained artificial intelligence algorithm model by using the temperature at the specific location of the battery and a cooling performance as an input; and predicting a possibility of thermal runaway based on the state information of the battery.

### BRIEF DESCRIPTION OF FIGURES

A brief description of each drawing is provided to more sufficiently understand the drawings cited in the detailed description of the present disclosure.

FIG. 1 is a conceptual diagram illustrating the basic principles of an artificial intelligence structure according to an embodiment of the present disclosure.

FIG. 2 is a flowchart illustrating a method for predicting thermal runaway using artificial intelligence according to an embodiment of the present disclosure.

FIG. 3 illustrates a mechanism by which a thermal runaway prediction apparatus generates a virtual data SET according to an embodiment of the present disclosure.

FIG. 4 illustrates an example of a virtual heating curve data set according to an embodiment of the present disclosure.

FIG. 5 illustrates an example of a mathematical model for generating virtual data according to various embodiments of the present disclosure.

FIG. 6 is a diagram illustrating an example of a virtual data set for thermal runaway generated according to various embodiments of the present disclosure.

FIG. 7a illustrates a training mechanism of an artificial intelligence algorithm model for predicting thermal runaway in a thermal runaway prediction apparatus according to an embodiment of the present disclosure.

FIG. 7b is a graph showing temperature changes over time at a certain point of a battery according to an embodiment of the present disclosure.

FIG. 7c is a diagram for explaining an example of specific time domain information and a time difference between a specific time domain and a prediction time point according to an embodiment of the present disclosure.

FIG. 8 illustrates an inference mechanism in which a trained artificial intelligence algorithm model predicts thermal runaway according to an embodiment of the present disclosure.

FIG. 9 is a flowchart showing a sequence in which a thermal runaway prediction apparatus predicts thermal runaway according to an embodiment of the present disclosure.

FIG. 10 is a block diagram of a thermal runaway prediction apparatus to which an artificial intelligence algorithm model is applied according to an embodiment of the present disclosure.

FIG. 11 is a flowchart for explaining a method for predicting thermal runaway according to an embodiment of the present disclosure.

### DETAILED DESCRIPTION OF EXEMPLARY EMBODIMENTS

The technical concept of the present disclosure may be subject to various modifications and may have various embodiments. Specific embodiments are illustrated in the drawings and described in detail herein. However, this is not intended to limit the technical concept of the present disclosure to specific forms, and it should be understood to include all modifications, equivalents, and alternatives within the scope of the technical concept of the present disclosure.

In describing the technical concept of the present disclosure, detailed descriptions of related known technologies may be omitted if they are deemed to obscure the gist of the present disclosure. In addition, numerical labels (e.g., first, second, etc.) used in the description are merely for distinguishing one component from another.

As used herein, when one component is described as being “connected to” or “coupled to” another component, it should be understood that the component may be directly connected or coupled to the other component, or may be indirectly connected or coupled through another component, unless otherwise stated.

The terms such as “˜unit,” “˜mechanism,” and “˜er” described herein refer to a unit that processes at least one function or operation, and may be implemented with hardware such as a Processor, a Micro Processor, a Micro Controller, a Central Processing Unit (CPU), a Graphics Processing Unit (GPU), an Accelerate Processor Unit (APU), a Digital Signal Processor (DSP), an Application Specific Integrated Circuit (ASIC), a Field Programmable Gate Array (FPGA), or the like, software, or a combination of hardware and software.

And it is intended to clarify that the division of components in the present application is merely based on the main function performed by each component. That is, two or more components to be described below may be combined into one component, or one component may be provided by being divided into two or more parts according to more subdivided functions. Additionally, the classification of the components described herein is merely based on their respective main functions. Accordingly, two or more components may be combined into one, or a single component may be subdivided into two or more subcomponents by function. Each component may perform not only its main function but also part or all of the functions performed by other components. Conversely, part of the main function of a component may be dedicated to and performed by another component.

In describing embodiments of the present disclosure, detailed descriptions of related functions or configurations will be omitted when it is determined that they may unnecessarily obscure the gist of the present disclosure. The terms to be described later are terms defined in consideration of functions in the present disclosure, and may vary according to the intention or custom of the user or operator, and the like. Therefore, the definition should be made based on the entire content of the present specification.

For the same reason, some components in the attached drawings may be exaggerated, omitted, or schematically illustrated. In addition, the size of each component does not fully reflect the actual size. In each drawing, the same reference numerals are assigned to the same or corresponding components.

The advantages and features of the present disclosure and the method of achieving them will become clear by referring to the embodiments described in detail below with the attached drawings. However, the present disclosure is not limited to the embodiments disclosed below, but may be implemented in various different forms; rather, the embodiments are provided so that the description of the present disclosure is complete and to fully convey the scope of the invention to those skilled in the art to which the embodiments of the present disclosure pertain, and the scope to be claimed in the present disclosure is defined only by the scope of the claims.

At this time, it will be understood that each block of the flow chart illustrations, and combinations of the blocks in the flow chart illustrations, may be executed by computer program instructions. These computer program instructions may be mounted on a processor of a general purpose computer, a special purpose computer, or other programmable data processing equipment, so the instructions performed through the processor of the computer or other programmable data processing equipment create means for performing the functions described in the flowchart block(s). These computer program instructions may also be stored in a computer-usable or computer-readable memory that can direct a computer or other programmable data processing equipment to implement the functions in a particular manner, so the instructions stored in the computer-usable or computer-readable memory are capable of producing an article of manufacture including instruction means for performing the functions described in the flowchart block(s). The computer program instructions may also be loaded onto a computer or other programmable data processing equipment to cause a series of operational steps to be performed on the computer or other programmable data processing equipment to produce a computer implemented process such that the instructions that execute on the computer or other programmable data processing equipment provide steps for implementing the functions described in the flowchart block(s).

Also, each block may represent a module, segment, or portion of code that includes one or more executable instructions for implementing the specified logical function(s). It should also be noted that in some alternative implementations, the functions noted in the blocks may occur out of the order noted. For example, two blocks shown in succession may in fact be executed substantially concurrently or the blocks may sometimes be executed in the reverse order, depending upon the functionality involved.

The term ‘unit or part’ used in the present disclosure refers to a hardware component such as software or a Field-Programmable Gate Array (FPGA) or an Application Specific Integrated Circuit (ASIC), and the ‘unit’ may be configured to perform specific roles. However, a ‘unit’ is not limited to software or hardware. A ‘unit’ may be configured to reside on an addressable storage medium and configured to execute one or more processors. Thus, by way of example, a ‘unit’ may include components such as software components, object-oriented software components, class components, and task components, as well as processes, functions, attributes, procedures, subroutines, segments of program code, drivers, firmware, microcode, circuitry, data, databases, data structures, tables, arrays, and variables. The functionality provided by the components and ‘units’ may be combined into a smaller number of components and ‘units’ or further separated into additional components and ‘units’. Furthermore, the components and ‘units’ may be implemented to reproduce one or more CPUs within a device or a secure multimedia card. In an embodiment, a ‘unit’ may include one or more processors and/or devices. Hereinafter, embodiments according to the technical idea of the present disclosure will be described in detail in order.

Hereinafter, various embodiments according to the technical concept of the present disclosure will be described in detail.

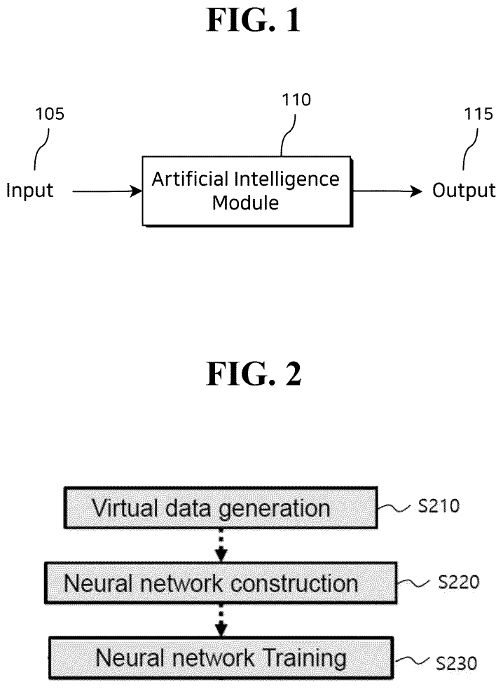

FIG. 1 is a conceptual diagram illustrating the basic principles of an artificial intelligence structure according to an embodiment of the present disclosure.

Referring to FIG. 1, the basic principles by which training is performed in an artificial intelligence structure are shown.

Artificial intelligence technology refers to technology for solving cognitive problems mainly associated with human intelligence, such as learning, problem-solving, and recognition. Artificial intelligence may be trained through a machine learning (ML) method and a deep learning (DL) method. Machine learning is a technique mainly used for pattern recognition and learning, and it refers to an algorithm that predicts subsequent data based on learning from recorded data. It refers to a technology that learns by itself from data without being based on predefined rules or patterns. On the other hand, deep learning is a field of machine learning and has the difference of processing data based on an Artificial Neural Network (ANN). Deep learning is capable of processing more complex and sophisticated operations than machine learning because it uses an artificial neural network. Types of algorithms for deep learning may include Convolutional neural network (CNN), Artificial neural network (ANN), Recurrent Neural Network (RNN), and the like.

Referring to FIG. 1, the artificial intelligence structure may be represented by an artificial intelligence module 110. The artificial intelligence module 110 receives certain input data 105, performs training through a certain method defined in the module, and outputs output data 115 regarding the training result. According to an embodiment, the input data 105 may include certain data, virtual data, an input sequence, temperature information, time information, virtual thermal information, and the like. The output data 115 may include virtual data, a latent specific factor, a battery state (temperature, SEI concentration, anode concentration, cathode concentration, electrolyte concentration), a predicted value, a thermal runaway possibility value, an output sequence, and the like.

FIG. 2 is a flowchart illustrating a method for predicting thermal runaway using artificial intelligence according to an embodiment of the present disclosure.

FIG. 2 may illustrate a method performed by a thermal runaway prediction apparatus according to an embodiment of the present disclosure. The thermal runaway prediction apparatus of FIG. 2 may be an apparatus including the artificial intelligence module 110 of FIG. 1. The thermal runaway prediction apparatus may include a plurality of artificial intelligence algorithm modules. The thermal runaway prediction apparatus is named as an apparatus, but it is not limited to a hardware configuration and may be a concept that includes a program, software, a system, and the like.

In step S210, the thermal runaway prediction apparatus may generate a virtual data set.

In step S220, the thermal runaway prediction apparatus may configure an artificial intelligence algorithm model for predicting thermal runaway.

In step S230, the thermal runaway prediction apparatus may train the configured artificial intelligence algorithm model using the generated virtual data. In an embodiment, the thermal runaway prediction apparatus may perform training until the error of the result value derived from the artificial intelligence algorithm model does not exceed a threshold value.

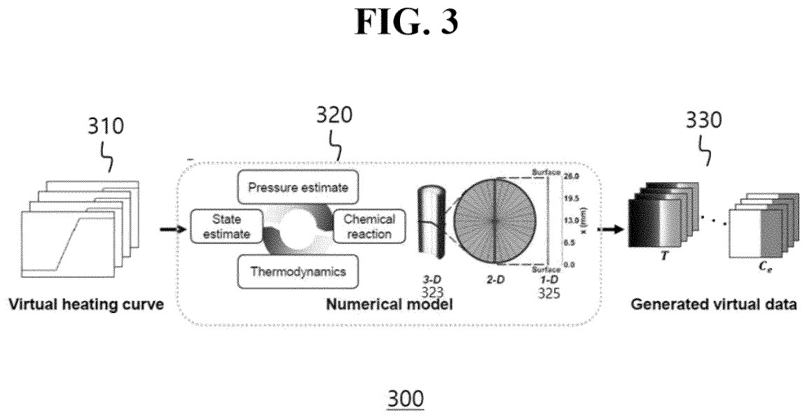

Hereinafter, how the thermal runaway prediction apparatus generates virtual data in step S210 will be specifically described with reference to FIG. 3 to FIG. 6.

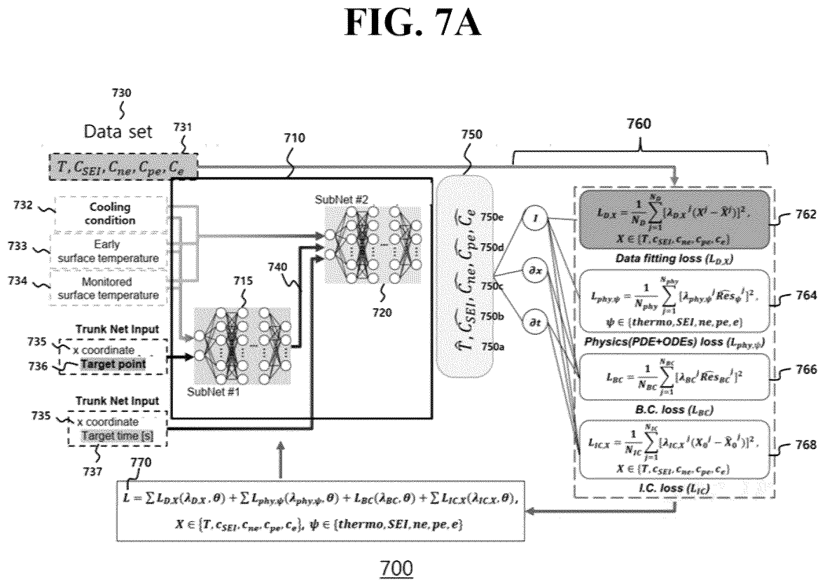

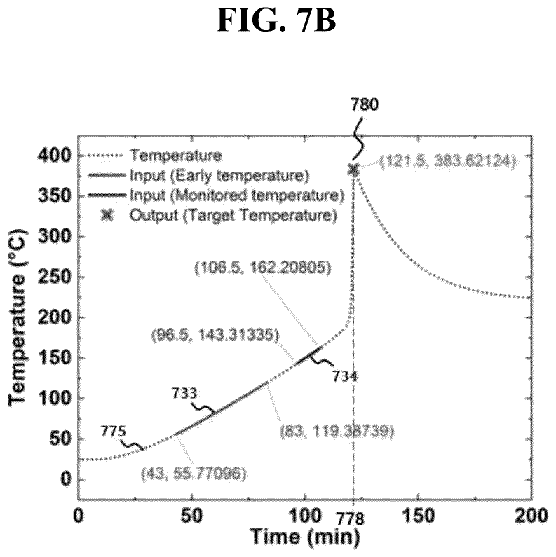

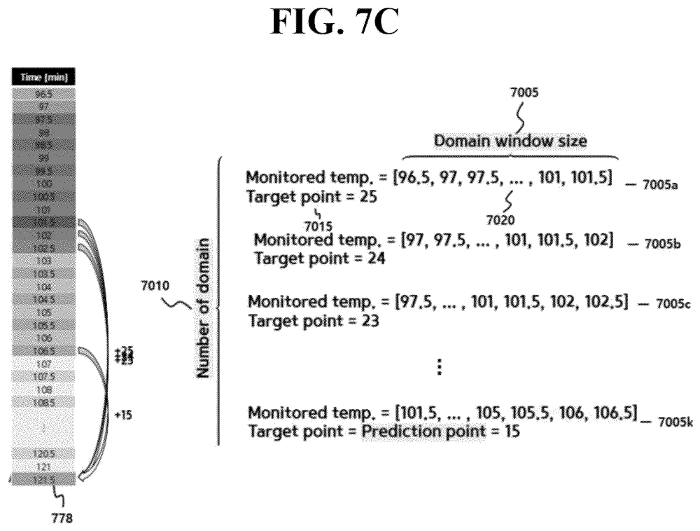

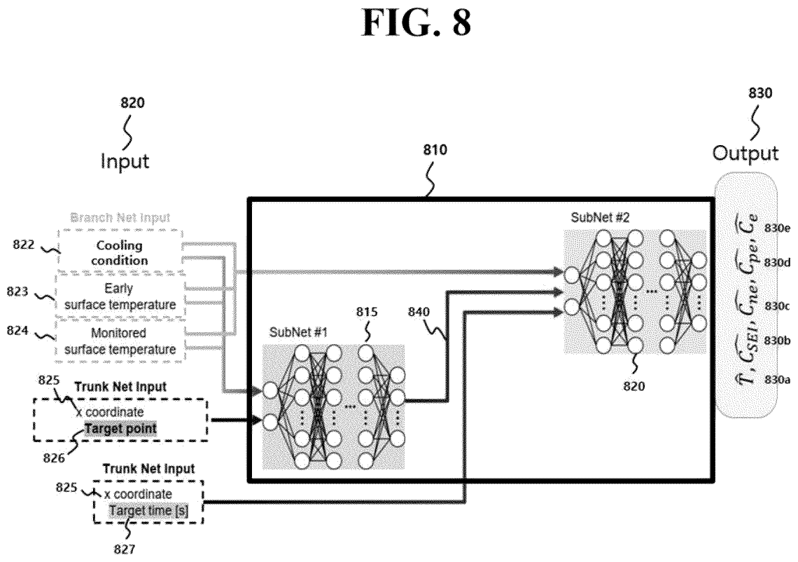

Hereinafter, how the thermal runaway prediction apparatus configures a neural network for predicting thermal runaway in step S220 will be specifically described with reference to FIG. 7a to FIG. 8.

FIG. 3 illustrates a mechanism by which a thermal runaway prediction apparatus generates a virtual data set according to an embodiment of the present disclosure.

The virtual data of FIG. 3 may be the same as the virtual data set described in FIG. 2. The thermal runaway prediction apparatus of the present disclosure may perform a series of operations of FIG. 3.

Referring to FIG. 3, the thermal runaway prediction apparatus may generate a virtual data set 330 by calculation through a numerical model 320 using a virtual heating curve data set 310.

In order to generate the virtual data set 330 using the numerical model 320 proposed in the present disclosure, a virtual heating curve data set 310 is needed as input data. The virtual heating curve data set 310 is represented as a line on a time-temperature graph. The virtual heating curve data set 310 represents the change in heat according to various scenarios configured with virtual scenarios, actual thermal runaway experiment scenarios, and the like.

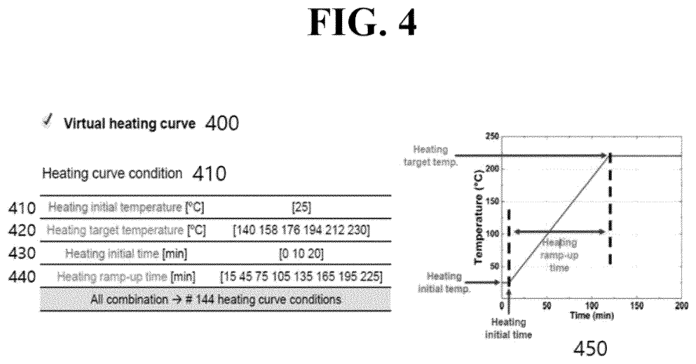

FIG. 4 is a diagram illustrating an example of a virtual heating curve data set according to an embodiment of the present disclosure.

The virtual heating curve data 400 represents the change in temperature over time according to various scenarios.

The virtual heating curve data 400 may include an initial temperature 410, a target temperature 420, an initial heating time 430, and a heating time 440 to the target temperature.

Referring to FIG. 4, the initial temperature 410 may represent the initial temperature when heating begins. For example, the initial temperature may be 25 degrees Celsius (hereinafter, ° C.).

The target temperature 420 may represent the temperature at which heating is terminated. For example, the target temperature may be 140° C., 158° C., 176° C., 194° C., 212° C., or 230° C.

The initial heating time 430 may be the time at which heat starts to be applied. For example, the initial heating time may include 0 minutes, 10 minutes, and 20 minutes.

The heating time 440 to the target temperature may be the time it takes for the temperature to reach from the initial temperature to the target temperature from the initial heating time. For example, the heating time to the target temperature may include 15 minutes, 45 minutes, 75 minutes, 105 minutes, 135 minutes, 165 minutes, 195 minutes, and 225 minutes.

The virtual heating curve data set may include heating curve data 400 corresponding to various scenarios using the four elements. In the above example, the virtual heating curve data set may include a total of 144 heating curve data 400 (1×6×3×8).

The thermal runaway prediction apparatus of the present disclosure may generate a variety of virtual heating curve data sets by combining the virtual heating curve data.

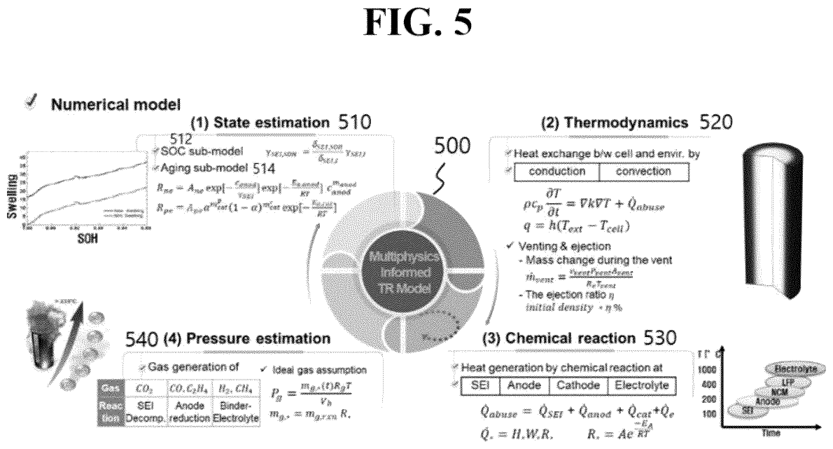

FIG. 5 is a diagram illustrating an example of a mathematical model for generating virtual data according to various embodiments of the present disclosure.

The mathematical model 500 of FIG. 5 may be a calculation model included in the thermal runaway prediction apparatus. The mathematical model 500 may be the same as or similar to the numerical model 320 described in FIG. 3. The mathematical model 500 may generate a virtual data set by performing calculations with the virtual heating curve data generated as in FIG. 4 as input.

The mathematical model 500 of FIG. 5 may include four types of multi-physics calculation models to explain the physical phenomena of a battery. For example,

First, the mathematical model 500 may include a state estimation model 510. The state of the battery may include the state of charge (SOC) and state of health (SOH) of the battery. The state of the battery can have a great influence on the chemical reactions of the internal components of the battery. The degree to which the thermal runaway of the battery depends on SOC and SOH may be determined using the reaction rate constants of the anode and cathode.

The state estimation model 510 may include an SOC sub-model 512 and an aging sub-model 514.

The SOC sub-model 512 utilizes the fact that the characteristics of SOC have a high relevance to thermal runaway through various studies. The higher the SOC, the more stored energy there is and the instability of the electrodes increases, so the amount of heat released during thermal runaway increases as the SOC increases. Therefore, the SOC sub-model 512 models the dependence of thermal runaway on SOC by adjusting the anode activation energy and reaction rate of the battery.

The aging sub-model 514 represents a multi-physics phenomenon composed of various aging mechanisms such as the formation of a solid electrolyte interphase (SEI) layer, material loss, and active material loss. Through various studies, it has been revealed that the aging mechanism has a direct relationship with the electrochemical degradation and cell swelling of the battery. Specifically, it was confirmed that electrochemical degradation occurs, a layer is formed on the electrode, and as this layer thickens, cell swelling occurs. That is, the reaction rate constant of the anode related to thermal runaway can be identified because the SEI layer thickens due to the aging mechanism.

$${γ}_{SEI , SOH} = \frac{{δ}_{SEI , SOH}}{{δ}_{SEI , I}} {γ}_{SEI , I} \qquad [ Equation 1 ]$$

Here, δ_{SEI,I} represents the initial thickness of the SEI layer, γ_{SEI,I} represents the initial thickness of the anode, and γ_{SEI,SOH} may represent the thickness ratio of the SEI layer according to SOH. The initial thickness represents a new battery state and may be interpreted as 100% SOH.

Second, the mathematical model 500 may include a thermodynamics model 520. The thermodynamics model 520 may estimate the heat propagation inside the battery cell and the heat balance between the cell and the environment, and may reproduce venting and ejection phenomena. The thermodynamics model 520 may include a heat generation rate (\dot{Q}_{abuse}) under abuse conditions to represent the temperature rise during thermal runaway.

In the thermodynamics model 520, the heat balance including heat conduction and propagation inside the battery when venting and ejection are considered during thermal runaway may be expressed as follows.

$$η ρ {c}_{p} ( \frac{\partial T}{\partial t} ) = ∇ k ∇ T + {\dot{Q}}_{a b u s e} + {\dot{Q}}_{r e v} + {\dot{Q}}_{o h m} + {\dot{m}}_{vent} {h}_{vent} \qquad [ Equation 2 ]$$

Here, η, ρ, cₚ, T, k, \dot{Q}_{abuse}, \dot{Q}ᵣₑᵥ, \dot{Q}ₒₕₘ, \dot{m}ᵥₑₙₜ, hᵥₑₙₜ may represent the discharge ratio, cell density, specific heat capacity, temperature, thermal conductivity of the cell, heat generation rate from chemical reactions of major substances under abuse conditions, reversible heat, resistive heat, mass change during venting, and specific enthalpy of vapor at the vent outlet, respectively.

In particular, various heat sources may exist inside the cell depending on various conditions, and among them, reversible heat and resistive heat may be dominant in extreme operating conditions (i.e., electrical abuse situations). In addition, the heat generated under abuse conditions may be dominant in thermal abuse situations. However, the present disclosure ignores the two heat sources and deals with changes in temperature and pressure in thermal abuse situations, and the heat balance may be summarized as follows.

$$η ρ {c}_{p} ( \frac{\partial T}{\partial t} ) = ∇ k ∇ T + {\dot{Q}}_{a b u s e} + {\dot{m}}_{vent} {h}_{vent} \qquad [ Equation 3 ]$$

The energy balance equation may include the main heat sources and venting and ejection phenomena in thermal abuse situations. The gas inside the cell may be released when the safety valve opens, and an endothermic reaction occurs during the release, causing the temperature to decrease slightly. The last term on the right side of Equation 3 represents the mass change during gas release. The mass change during discharge may be expressed as follows.

$${m}_{vent} = \frac{( {v}_{vent} {P}_{vent} {A}_{vent} )}{{R}_{e} {T}_{vent}} {P}_{vent} = \frac{P}{1 + {( \frac{μ - 1}{2} {M}^{2} )}^{\frac{μ}{μ - 1}}} {T}_{vent} = \frac{T}{( 1 + \frac{μ - 1}{2} {M}^{2} )} {v}_{vent} = M \sqrt{μ {R}_{e} {T}_{vent}} \qquad [ Equation 4 ]$$

Here, vᵥₑₙₜ, Pᵥₑₙₜ, Aᵥₑₙₜ, μ, M, Rₑ may represent the outlet velocity, vent pressure, vent cross-sectional area, specific heat ratio, Mach number, and gas constant of the electrolyte, respectively.

Ejection follows the vents, which means that the jelly roll ruptures and separates from the cell. Ejection is modeled by assuming that the mass of the cell decreases by η, which is in the range of 0-100%, due to explosion and flame. From a thermodynamic perspective, ejection may only affect the heat capacity of Equation 3. It is assumed that this ejection occurs only in the combustion of the cathode.

In addition, the heat balance between the cell and the environment due to convection may be expressed as follows.

$$- k ∇ T = {h}_{conv} ( T - {T}_{amb} ) + εσ ( {T}^{4} - {T}_{amb}^{4} ) = {h}_{conv} ( T - {T}_{amb} ) \qquad [ Equation 5 ]$$

Here, k, h_{conv}, ε, and σ may represent thermal conductivity, heat transfer coefficient, emissivity, and the Stefan-Boltzmann constant, respectively. The temperature may be calculated for each node.

Third, the mathematical model 500 may include a chemical reaction model 530. The chemical reaction model 530 may estimate the coupled degradation of chemical species during thermal runaway. The exothermic reaction of the battery follows the Arrhenius law. Q calculated in the chemical reaction model 530 may be transferred to the thermodynamics model 520 to represent the temperature change at each point of the cell. The estimated temperature change may be transferred back to the chemical reaction model 530 over time.

The heat generation rate by the chemical reaction estimated in the chemical reaction model 530 is as follows.

$${\dot{Q}}_{abuse , *} = {H}_{*} {W}_{*} {R}_{*} \qquad [ Equation 6 ]$$

Here, H_{*}, W_{*}, and R_{*} may represent the heat release, the content of characteristic active material, and the reaction rate of the cell component, respectively. * represents the SEI layer, anode, cathode, or electrolyte, and for example, the reaction can start at 90 degrees or 200 degrees, respectively.

H_{*} and W_{*} are constant but vary depending on the material, and R_{*} may be expressed as a function of temperature and time according to the Arrhenius law. In particular, the reaction rate of the SEI layer or the electrolyte may be calculated as follows.

$${R}_{*} = {A}_{*} exp [ - \frac{{E}_{a , *}}{RT} ] {c}_{*}^{{m}_{*}} \qquad [ Equation 7 ]$$

Here, A_{*}, E_{a,*}, R, c_{*}, and m_{*} may represent the reaction factor, activation energy, gas constant, dimensionless concentration, and frequency factor of component *, respectively.

Specifically, the reaction rates of the anode and cathode are as follows, respectively.

$${R}_{anod} = {A}_{anod} exp [ - \frac{{c}_{anod}}{{γ}_{SEI}} ] exp [ - \frac{{E}_{a , anod}}{RT} ] {c}_{anod}^{{m}_{anod}} \qquad [ Equation 8 ]$$

$${R}_{cat} = {A}_{cat} {{a}^{{m}_{cat}^{p}} ( 1 - α )}^{{m}_{cat}^{r}} exp [ - \frac{{E}_{a , cat}}{RT} ]$$

Here, the thickness ratio of the SEI layer is defined in the state estimation model 510, and represents the reaction rate of the anode that changes the temperature path during thermal runaway. In addition, α,

$${m}_{cat}^{p} , and {m}_{cat}^{r}$$

are the degree of conversion of active material at the cathode, the reaction order of the cathode with respect to α, and the reaction order with respect to (1−α), respectively. The reaction of the cathode may define A_{cat} and E_{a,cat} in the state estimation model 510 and may explain the SOC of the battery.

In conclusion, the total heat generation rate of the cell during thermal abuse may be expressed as follows.

$${\dot{Q}}_{abuse} = {\dot{Q}}_{SEI} + {\dot{Q}}_{anod} + {\dot{Q}}_{cat} + {\dot{Q}}_{e} \qquad [ Equation 9 ]$$

Here, just as the chemical decomposition of each species varies with temperature, the heat due to chemical decomposition may vary with temperature.

Fourth, the mathematical model 500 may include a pressure estimation model 540. The calculated cell temperature change and reaction rate are transferred to the pressure estimation model 540, and the pressure estimation model 540 may calculate the internal pressure change of the cell due to gas generation and growth during thermal runaway based on this. The pressure estimation model 540 may consider the physical properties of five major gases: CO, C₂H₄, CO₂, H₂, and CH₄. The formation of these five gases may be calculated by the chemical reaction rates of three chemical species. Here, the three chemical species are divided into CO₂ and CO, C₂H₄ and H₂, and CH₄, respectively.

Gas generation during thermal runaway is a multi-physics phenomenon and is difficult to measure without installing various gas detectors. Therefore, gas formation may be estimated by measuring the internal pressure of the cell. To facilitate the estimation, ideal gas conditions are assumed, and the control volume of the entire canister is assumed to be the same as the control volume of the cell. The internal pressure of the cell is composed of the partial pressure of saturated electrolyte vapor and gas and may be expressed as follows.

$$P = {P}_{sat} + {P}_{g} \qquad [ Equation 10 ]$$

Here, Pₛₐₜ and P_{g} may represent the pressure generated from the saturated electrolyte liquid and the pressure generated due to gas formation, respectively.

The pressure induced by gas formation due to the decomposition of each chemical component may be expressed as follows.

$${P}_{{g}^{*}} = \frac{{m}_{{g}^{*}} ( t ) {R}_{g} T}{V} \qquad [ Equation 11 ]$$

Here, P_{g*}, m_{g*}=(t), R_{g}, T, and V may represent the partial pressure of the gas component, the mass of the gas component, the gas constant, the cell temperature, and the control volume, respectively. * may represent the SEI layer, anode, or electrolyte. In addition, it is assumed that the evolution of gas mass has a high correlation with the chemical reaction rate as shown in the following equation.

$${m}_{{g}^{*}} ( t ) = {m}_{g , rxn} {R}_{*} \qquad [ Equation 12 ]$$

Here, m_{g,rxn} may represent the initial mass of the reactive gas. Equation 12 explains gas formation from three chemical components by correlating the five components of gas formation with chemical reactions.

CO₂ may be calculated from the decomposition of the SEI. CO and C₂H₄ may be generated by being reduced at the anode, so they can be generated by calculating the reaction rate of anode decomposition. H₂ may be released from the binder during thermal runaway. CH₄ may be generated from the decomposition of the organic electrolyte.

The mathematical model 500 of FIG. 5 combines and uses the four types of multi-physics models, and may numerically estimate the thermal runaway phenomenon of the battery by using a one-dimensional finite element model 325 that simplifies the geometric structure for the 3D model 323 of FIG. 3. That is, information on the entire battery can be estimated using the gradient. The virtual data set 330 can be generated by applying thermal runaway through the mathematical model 500 using the virtual heating curve data set obtained in FIG. 4.

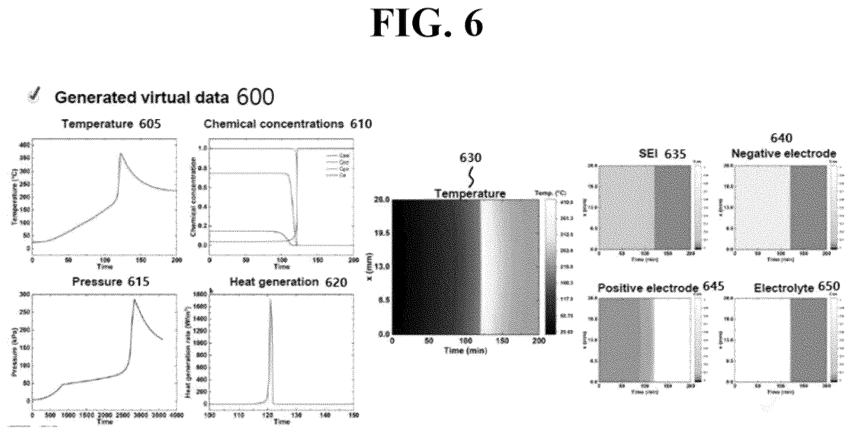

FIG. 6 is a diagram illustrating an example of a virtual data set for thermal runaway generated according to various embodiments of the present disclosure.

The virtual data set 600 of FIG. 6 may represent the virtual data set 330 of FIG. 3, and may represent a virtual data set generated by applying the virtual heating curve data set 400 generated in FIG. 4 to the mathematical model 500 of FIG. 5.

The virtual data set 600 may include data representing the state of the battery. The virtual data set 600 may include information representing the change of data over time for a 1D model of the battery, and based on this, may include information representing the change of specific data for the battery location over time.

Referring to FIG. 6, the virtual data set 600 may include temperature information over time 605, chemical concentration information over time 610, pressure information over time 615, and heat generation rate information over time 620 at a certain point of the battery.

In addition, the virtual data set 600 may include, as information according to battery location, temperature information over time 630, SEI concentration information 635, anode concentration information 640, cathode concentration information 645, and electrolyte concentration information 650.

For example, FIG. 6 shows a battery with a size of 0 mm to 26 mm, where the x-axis represents time, and the y-axis represents the position coordinate of the battery. According to an embodiment, the data of the virtual data set may be expressed as: {[battery surface temperature before threshold, battery surface temperature from 15 to 25 minutes before prediction time, predicted coordinate value (x), predicted time value (t)], [temperature x,t, SEI concentration x,t, anode concentration x,t, cathode concentration x,t, electrolyte concentration x,t]}.

Returning to FIG. 2, when the virtual data set is generated in the manner of FIG. 3 to FIG. 6, in step S220, the thermal runaway prediction apparatus may configure an artificial intelligence algorithm model for predicting thermal runaway.

FIG. 7a is a diagram illustrating a training mechanism of an artificial intelligence algorithm model for predicting thermal runaway in a thermal runaway prediction apparatus according to an embodiment of the present disclosure. FIG. 7b is a graph showing temperature changes over time at a certain point of a battery according to an embodiment of the present disclosure. FIG. 7c is a diagram for explaining an example of specific time domain information and a time difference between a specific time domain and a prediction time point according to an embodiment of the present disclosure.

The artificial intelligence algorithm model 710 of FIG. 7a may be the same as or similar to the artificial intelligence algorithm model described in FIG. 2. FIG. 7a to FIG. 7c may correspond to the operation for training the artificial intelligence algorithm model in step S230 of FIG. 2.

The artificial intelligence algorithm model 710 of FIG. 7a may include two sub-models. The first sub-model 715 and the second sub-model 720 may have the same or similar structure. The first sub-model 715 and the second sub-model 720 perform the role of approximating the solution of a nonlinear operator equation by learning the mapping from one function to another. According to an embodiment, the first sub-model 715 and the second sub-model 720 may be an artificial intelligence algorithm model similar to DeepONET (deep operator neural network).

According to an embodiment, the first sub-model 715 and the second sub-model 720 may be configured with a plurality of branch networks and one trunk network. For example, the first sub-model 715 includes three branch networks, and the second sub-model 720 may include four branch networks.

Referring to FIG. 7a, a generated virtual data set 730 may be used for training the artificial intelligence algorithm model 710. The virtual data set 730 may include the virtual data set and the virtual heating curve data generated in the manner described in FIG. 2 to FIG. 6.

The virtual data set 730 may include a battery data set 731, cooling performance 732, previous surface temperature information 733, monitored surface temperature information 734, battery location information 735, domain information and domain-prediction time difference 736, and prediction time point 737.

The battery data set 731 may include temperature information 731a, SEI concentration information 731b, anode concentration information 731c, cathode concentration information 731d, and electrolyte concentration information 731e, which are finally generated as in FIG. 6.

The cooling performance 732 may be information representing the characteristics and performance of a cooling system applied to the battery. For example, in the case of an air-cooling system, it may be information representing the temperature, velocity, specific heat, etc., of the cooling fluid. A forced convection coefficient may be included as a variable of the cooling performance 732.

The previous surface temperature information 733 may be information representing the surface temperature of the battery measured just before an arbitrary threshold. In addition, the previous surface temperature information 733 may represent surface temperature information including an arbitrary number of pieces of information from a certain time point when an arbitrary threshold is reached. For example, referring to FIG. 7b, when an arbitrary temperature threshold is 120° C. and data is recorded at 1-minute intervals, if the arbitrary number of pieces of information to be included is set to 41, it may represent the temperature information in 1-minute units from 40 minutes before the time point (approximately 84 minutes) when the temperature at a specific location of the battery exceeds 120° C. That is, it may include the surface temperature information from 43 minutes to 83 minutes.

The monitored surface temperature information 734 may be information representing the battery surface information for a certain period of time after an arbitrary threshold. For example, when the monitored surface temperature information 734 in FIG. 7b represents the surface temperature measured between 96.5 minutes and 106.5 minutes, it may represent a total of 11 temperature values in 1-minute units. In an embodiment, the monitored surface information 734 may include surface information for a range of an arbitrary certain time before the prediction time point. For example, in FIG. 7b, if the prediction time is 121.5 minutes and an arbitrary certain time is determined as 15 to 25 minutes, it may include the battery surface temperature information from 96.5 minutes to 106.5 minutes.

The location information 735 may represent the coordinate value when the location of the battery determined in the virtual data set is represented by a one-dimensional coordinate. For example, in the case of a battery with a length of 26 mm, if the battery location information 735 is 0 or 26, it may represent the surface of the battery, and if it is 13, it may represent the center point of the battery.

In the domain information and domain-prediction time difference (target point) 736, the domain information may include the window size of the domain, the number of domains, and measurement time information within the window. For example, referring to FIG. 7c, when the prediction time point 778 is 121.5 minutes, the number of domains 7010 is 11, the domain window size 7005 is 11, the measurement time information 7020 within the window in the first domain 7000a is included at 0.5 intervals from 96.5 to 101.5, and the time difference 7015 between a specific time domain and the prediction time point may be 25. The 11 domains, from the first domain 7000a to the eleventh domain 7000k, may each include different measurement time information within the window and the time difference 736 between a specific time domain and the prediction time point.

The prediction time point 737 may be information representing the time point to be predicted. For example, in FIG. 7b, the prediction time point 737 may be 121.5.

Here, the temperature information may be information obtained from the heating curve data.

In an embodiment, the form of the data set 730 may be represented as: {[cooling performance (732), previous surface temperature information (733), monitored surface temperature information for a specific time (734), location information (735)(x), prediction time point (737(t))], [temperature x,t, SEI_concentration x,t, anode_concentration x,t, cathode_concentration x,t, electrolyte_concentration x,t]}. For example, if information for battery location 0 and time point 100 is needed from the data set, {[5, (55.77, 56.46, 57.16, . . . , 117.68, 118.53, 119.38), (temperature_0,75, temperature_0,75.5, temperature_0,76, . . . , temperature_0,84, temperature_0,84.5, temperature_0,85), 0, 100], [temperature_0,100, SE1_concentration_0,100, anode_concentration_0,100, cathode_concentration_0,100, electrolyte_concentration_0,100]} may be used.

Again, referring to FIG. 7a, the cooling performance 732, the previous surface temperature information 733, the monitored surface temperature information 734, the battery location information 735, the domain information and the domain-prediction time difference 736 are input to the artificial intelligence algorithm model 710 and may be input to the first sub-model 715.

In the first sub-model 715, the cooling performance 732, the previous surface temperature information 733, and the monitored surface temperature information 734 are each input to different branch networks, and the battery location information 735, the domain information and the domain-prediction time difference 736 may be input to a trunk network.

The first sub-model 715 may extract a latent feature factor 740 by learning the input information, which includes the cooling performance 732, the battery location information 735, the monitored surface temperature information 734, and the domain information and the domain-prediction time difference 736. The latent feature factor 740 may be information extracted for a single specific time from various local time information of the battery. The latent feature factor 740 may include latent features of temperature, SEI concentration, anode concentration, cathode concentration, and electrolyte concentration at a specific location of the battery in a predetermined time domain.

The second sub-model 720 may perform training with the cooling performance 732, the previous surface temperature information 733, and the monitored surface temperature information 734, which are input to the artificial intelligence algorithm model 710, and the latent feature factor 740 extracted from the first sub-model 715, the battery location information 735, and the prediction time point 737 as inputs.

In the second sub-model 720, the cooling performance 732, the previous surface temperature information 733, the monitored surface temperature information 734, and the latent feature factor 740 are each input to different branch networks, and the battery location information 735 and the prediction time point 737 may be input to a trunk network.

The second sub-model 720 may respectively output a predicted temperature 750a, a predicted SEI concentration 750b, a predicted anode concentration 750c, a predicted cathode concentration 750d, and a predicted electrolyte concentration 750e for a specific location and prediction time point of the battery under the input conditions.

The output layer of the artificial intelligence algorithm model 710 may be configured with nodes proportional to the number of final output values, and may be configured with 100 nodes for each parameter. For example, since the value output in FIG. 7a is a total of 5, it may be configured with a total of 500 nodes.

The artificial intelligence algorithm model 710 may determine a multiphysics informed loss 760 for training by using the outputted predicted thermal runaway information 750 and the battery data set 731 included in the data set.

The multiphysics loss 760 may include at least one loss item. The loss items may include a data fitting loss 762, a physics loss 764, a boundary condition loss 766, and an initial condition loss 768.

A final loss (L) 770, determined by adjusting each loss of the multiphysics loss 760 according to a weight, may be expressed as follows.

$$L = \sum {L}_{D , X} ( {λ}_{D , X} , θ ) + \sum {L}_{phy , ψ} ( {λ}_{phy , ψ} , θ ) + {L}_{BC} ( {λ}_{BC} , θ ) + \sum {L}_{IC , X} ( {λ}_{IC , X} , θ ) , \qquad [ Equation 13 ]$$

$$X ∈ \{ T , {c}_{SEI} , {c}_{ne} , {c}_{pe} , {c}_{e} \} , ψ ∈ \{ thermo , SEI , ne , pe , e \} ,$$

Here, L_{D,X} denotes the data fitting loss 762, L_{phy,ψ} denotes the physics loss 764, L_{BC} denotes the boundary condition loss 766, L_{IC,X} denotes the initial condition loss 768, λ denotes the adaptive weights for each loss, and θ denotes the trainable parameters of the artificial intelligence algorithm model.

Specifically, each of the multiphysics losses 760 may be determined as in the following Equations 14 to 17.

$${L}_{D , X} = \frac{1}{{N}_{D}} {\text{?} [ {{λ}_{D , X}}^{j} ( {X}^{j} - {\hat{X}}^{j} ) ]}^{2} , X ∈ \{ T , {c}_{SEI} , {c}_{ne} , {c}_{pe} , {c}_{e} \} \qquad [ Equation 14 ]$$

$$\text{?} = \frac{1}{\text{?}} {\text{?} [ \text{?} ]}^{2} , ψ ∈ \{ thermo , SEI , ne , pe , e \} \qquad [ Equation 15 ]$$

$$\text{?} \text{indicates text missing or illegible when filed}$$

Here, the physics loss may represent a combined loss to which both PDE and ODE are applied. In addition, the physics loss (physics loss) prevents data overfitting, suppresses non-physical predictions, and plays a role in enabling robust predictions.

$${L}_{BC} = \frac{1}{{N}_{BC}} {{\sum }_{j = 1}^{{N}_{BC}} [ {{λ}_{BC}}^{j} ]}^{2} . \qquad [ Equation 16 ]$$

$${L}_{IC , X} = \frac{1}{{N}_{IC}} {{\sum }_{j = 1}^{{N}_{IC}} [ {{λ}_{IC , X}}^{j} ( {{X}_{0}}^{j} - {{\hat{X}}_{0}}^{j} ) ]}^{2} , \\ X ∈ \{ T , {c}_{SEI} , {c}_{ne} , {c}_{pe} , {c}_{e} \} . \qquad [ Equation 17 ]$$

Here, N denotes the number of collocation points for each loss item, and Δ^{j} may represent the adaptive weight applied to the j-th collocation point. Xⱼ and \hat{X}ⱼ denote the actual value 731 and the predicted value 750 at the j-th collocation point in the collocation point set, respectively, and [symbol] denotes the residual of the thermal runaway governing equation considering the multiphysics characteristics of the battery.

The thermal runaway governing equations for each of the outputs and boundary conditions may be expressed as follows.

$$= ρ \text{?} \frac{\partial \text{?}}{\partial t} - k \frac{{\partial }^{2} \text{?}}{\partial {x}^{2}} + {H}_{SEI} {W}_{SEI} \frac{\partial t}{} + {H}_{ne} {W}_{ne} \frac{\partial t}{} \text{?} {H}_{pe} {W}_{pe} \frac{\partial t}{} + \text{?} \frac{\partial t}{} \qquad [ Equation 18 ]$$

$$= \frac{dt}{} + {A}_{SEI} exp [ - \frac{{E}_{a , SEI}}{\text{?}} ]$$

$$= \frac{dt}{} + {A}_{ne} exp [ - \frac{{γ}_{SEI}}{} ] exp [ - \frac{{E}_{a , ne}}{\text{?}} ]$$

$$= \frac{dt}{} \text{?} {A}_{pe} \text{?} ( 1 - ) exp [ - \frac{{E}_{a , pe}}{\text{?}} ]$$

$$= \frac{d \text{?}}{dt} + \text{?} exp [ - \frac{\text{?}}{\text{?}} ] \text{?}$$

$$= k \frac{\partial \text{?}}{\partial x} - \text{?} ( {T}_{Ext} - \text{?} )$$

$$\text{?} \text{indicates text missing or illegible when filed}$$

Here, NTK (Neural Tangent Kernel) may play a role in solving the imbalance of the loss function by assigning appropriate weights to each loss item.

The NTK of the artificial intelligence algorithm model 710, HNTK, may be determined as follows.

$${H}_{ij}^{NTK} ( {θ}_{n} ) = ( \frac{\text{?} ( {θ}_{n} )}{d {θ}_{n}} , \frac{\text{?} ( {θ}_{n} )}{d {θ}_{n}} ) , i , j = 1 , 2 , … , N , \qquad [ Equation 19 ]$$

$${T}^{k} ( {θ}_{n} ) = \{ \begin{matrix}\begin{matrix}{X}^{k} - \text{?} , & X ∈ \{ T , {c}_{SEI} , {c}_{ne} , {c}_{pe} , {c}_{e} \} , & 1 \leq k \leq 5 {N}_{D}\end{matrix} \\ \begin{matrix}, & ψ ∈ \{ thermo , SEI , ne , pe , e \} , & 5 {N}_{D} < k \leq 5 {N}_{D} + 5 {N}_{phy}\end{matrix} \\ \begin{matrix}, & 5 {N}_{D} + 5 {N}_{phy} < k \leq 5 {N}_{D} + 5 {N}_{phy} + {N}_{BC}\end{matrix} \\ \begin{matrix}{{X}_{0}}^{k} - \text{?} , & X ∈ \{ T , {c}_{SEI} , {c}_{ne} , {c}_{pe} , {c}_{e} \} , & 5 {N}_{D} + 5 {N}_{phy} + {N}_{BC} < k \leq N\end{matrix}\end{matrix}$$

$$\text{?} \text{indicates text missing or illegible when filed}$$

Here, θₙ may represent the parameters in the n-th iteration of the artificial intelligence algorithm model.

The adaptive weight may be calculated as in the following Equation 20.

$${λ}^{k} = {( \frac{{max}_{1 \leq k \leq N} {H}_{kk}^{NTK} ( {θ}_{n} )}{{H}_{kk}^{NTK} ( {θ}_{n} )} )}^{\frac{1}{2}} \qquad [ Equation 20 ]$$

By integrating the adaptive weights into the gradient descent method, the convergence speed can be improved in nonlinear scenarios such as the thermal runaway phenomenon of a battery.

The artificial intelligence algorithm model 710 performs training using the integrated final loss 770 through the adaptive weights and may update each parameter.

FIG. 8 is a diagram illustrating an inference mechanism in which a trained artificial intelligence algorithm model predicts thermal runaway according to an embodiment of the present disclosure.

The trained artificial intelligence algorithm model 810 of FIG. 8 may be an artificial intelligence algorithm module whose training has been completed in the same manner as in FIG. 7a to FIG. 7c.

In FIG. 8, the state of the battery at a specific location and at a specific time point may be predicted by measuring the temperature of the battery under a certain cooling performance, thereby predicting thermal runaway.

Referring to FIG. 8, cooling performance 822, early surface temperature information 823, monitored surface temperature information 824, location information 825, domain information and domain-prediction time difference 826, and prediction time point 827 may be used as input 820 to the trained artificial intelligence algorithm model 810.

When the inputs 820 are received, the trained artificial intelligence algorithm model 810 may respectively output a predicted temperature 830a, a predicted SEI concentration 830b, a predicted anode concentration 830c, a predicted cathode concentration 830d, and a predicted electrolyte concentration 830e as output 830.

In the present disclosure, only the five parameters have been described, but based on various information included in the data set, gas production amount, battery internal pressure, etc., may be trained and predicted.

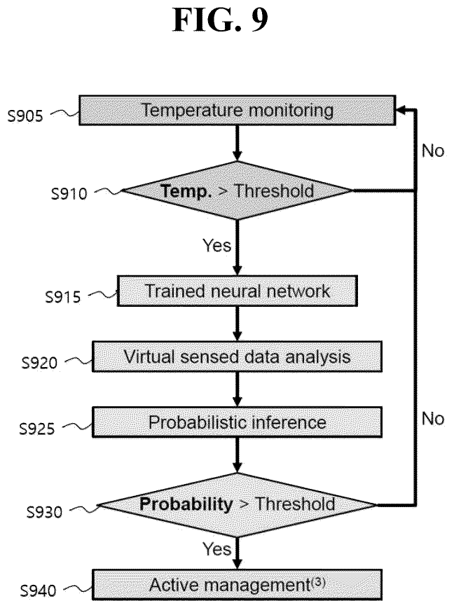

FIG. 9 is a flowchart showing a sequence in which a thermal runaway prediction apparatus predicts thermal runaway according to an embodiment of the present disclosure.

In FIG. 9, the trained artificial intelligence algorithm model may be the same as or similar to the trained artificial intelligence algorithm model 810 in FIG. 8.

In step S905, the thermal runaway prediction apparatus may monitor the temperature of the battery.

In step S910, the thermal runaway prediction apparatus may determine whether the monitored temperature exceeds a specific threshold.

In an embodiment, the thermal runaway prediction apparatus may apply the thermal runaway prediction mechanism when the temperature exceeds a specific threshold. Alternatively, when the monitored temperature does not exceed the specific threshold, the thermal runaway prediction apparatus may continuously monitor the temperature of the battery.

In step S915, when the temperature exceeds the threshold, the thermal runaway prediction mechanism may perform the thermal runaway prediction mechanism using the trained artificial intelligence algorithm model.

In step S920, when the thermal runaway prediction mechanism is performed, the thermal runaway prediction apparatus virtually senses the internal state of the battery using the trained artificial intelligence algorithm model and may output predicted state information of the battery. Here, the predicted state information of the battery may include the predicted temperature and predicted concentration values output in FIG. 7a to FIG. 8.

In step S925, the thermal runaway prediction apparatus may infer the possibility of thermal runaway using the predicted state information. The possibility of thermal runaway may be determined based on the slope of the temperature response, the concentration of components, the change in internal pressure of the battery, and so on. For example, the thermal runaway prediction apparatus may determine that thermal runaway has occurred if the slope of the temperature response changes more steeply than a certain slope. Or, the thermal runaway prediction apparatus may determine the time point when the reaction of the anode concentration starts as the thermal runaway occurrence point. The thermal runaway prediction apparatus may infer the possibility of thermal runaway by comprehensively considering various factors.

In step S930, the thermal runaway prediction apparatus may determine whether the inferred possibility of thermal runaway exceeds a threshold.

In an embodiment, if the inferred possibility of thermal runaway does not exceed the threshold, the thermal runaway prediction apparatus may return to step S905 and monitor the temperature of the battery. If the thermal runaway prediction apparatus's possibility of thermal runaway exceeds the threshold, various systems for controlling thermal runaway may be activated in step S940.

Here, the various systems for controlling thermal runaway may be performed through various methods such as a phase transition actuator, a cooling system, etc., and a description thereof will be omitted.

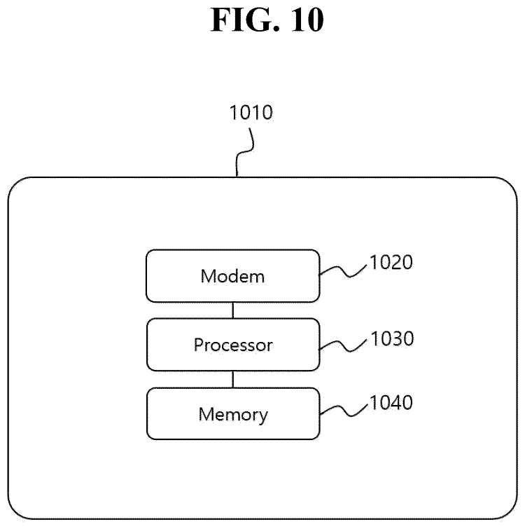

FIG. 10 is a block diagram of a thermal runaway prediction apparatus to which an artificial intelligence algorithm model is applied according to an embodiment of the present disclosure.

Referring to FIG. 10, the thermal runaway prediction apparatus 1010 may include a modem 1020, a memory 1040, and a processor 1030.

The modem 1020 may be a communication modem that is electrically connected to other electronic devices to enable mutual communication. In particular, the modem 1020 may receive data input and transmit it to the processor 1030, and the processor 1030 may store the input data value in the memory 1040. In addition, it may transmit information output by the artificial intelligence algorithm trained in the system to other electronic devices.

The memory 1040 is a component where various information and program commands for the operation of the thermal runaway prediction apparatus 1010 are stored, and may be a storage device such as a Hard Disk, SSD (Solid State Drive), or the like. In particular, the memory 1040 may store one or more data input values input from the modem 1020 under the control of the processor 1030. In addition, the memory 1040 may store program commands such as a thermal runaway prediction artificial intelligence algorithm that can be executed by the processor 1030.

The processor 1030 is configured with at least one processor and may calculate data by utilizing a mathematical calculation model, a thermal runaway prediction artificial intelligence algorithm, and a trained thermal runaway prediction artificial intelligence algorithm using the data and program commands stored in the memory 1040. The processor 1030 may control and utilize the thermal runaway prediction apparatus and all artificial intelligence algorithm models (for example, an artificial intelligence algorithm model, a trained artificial intelligence algorithm model including a DeepONET model) described in FIG. 1 to FIG. 9.

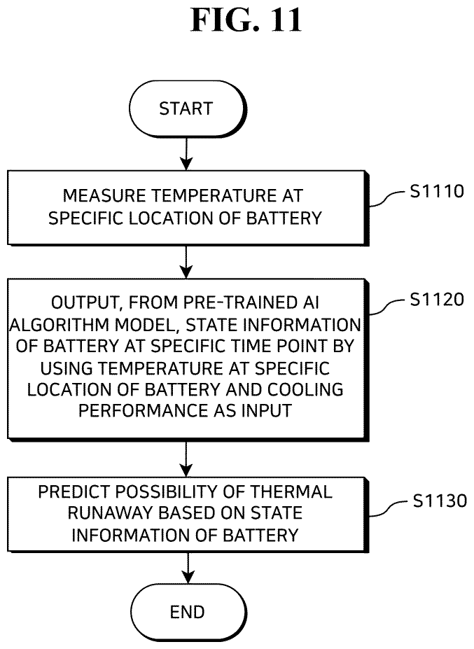

FIG. 11 is a flowchart for explaining a method for predicting thermal runaway according to an embodiment of the present disclosure.

Hereinafter, referring to FIG. 11, the thermal runaway prediction method of the artificial intelligence algorithm of the thermal runaway prediction apparatus, the training and implementation method of the artificial intelligence algorithm model described with reference to FIG. 1 to FIG. 9 will be summarized and explained. Each operation is not necessarily an essential operation to be included in a series of processes, and only a part may be configured and operated depending on the situation.

In step S1110, the thermal runaway prediction apparatus may measure the temperature at a specific location of the battery (for example, the surface temperature information 822, the monitored surface temperature information 824 of FIG. 8).

According to an embodiment, the specific location of the battery may include at least one of the surface of the battery and the interior of the battery.

In step S1120, the thermal runaway prediction apparatus may output state information of the battery at a specific time point (for example, the output 830 of FIG. 8) from a pre-trained artificial intelligence algorithm model (for example, the trained artificial intelligence algorithm model 810 of FIG. 8) by using the temperature at the specific location of the battery and the cooling performance (for example, the cooling performance 822 of FIG. 8) as an input.

According to an embodiment, the cooling performance includes the performance of a cooling system applied to the battery, and the performance of the cooling system may include the temperature, velocity, specific heat, and forced convection coefficient of a cooling fluid applied to the battery.

According to an embodiment, the pre-trained artificial intelligence algorithm model is configured as a single artificial intelligence model or is configured with two or more sub-models, wherein the artificial intelligence model or the two or more sub-models each comprises a plurality of branch networks and a trunk network, and the artificial intelligence model or the two or more sub-models are pre-trained by using, as an input, the cooling performance, state information of the battery included in a virtual data set, a temperature of the battery, a battery location information, a prediction time point, and domain information (for example, the domain information and domain-prediction time difference 826 of FIG. 8).

According to an embodiment, the virtual data set (for example, the virtual data set 730 of FIG. 7a) is generated through a multi-physics calculation model (for example, the mathematical model 500 of FIG. 5) based on a virtual heating curve data set (for example, the virtual heating curve data set 310 of FIG. 3) determined from a virtual scenario, and the virtual heating curve data set is determined by a combination of an initial temperature, an initial time, a heating target temperature, and a heating time (for example, the initial temperature 410, target temperature 420, initial heating time 430, and heating time to target temperature 440 of FIG. 4), and the multi-physics calculation model may include a state estimation model, a thermodynamics model, a chemical reaction model, and a pressure estimation model related to an occurrence of thermal runaway of the battery (for example, the state estimation model 510, thermodynamics model 520, chemical reaction model 530, and pressure estimation model 540 of FIG. 5).

According to an embodiment, the pre-trained artificial intelligence algorithm model may be trained based on a final loss determined based on the outputted predicted state information of the battery and the state information of the battery (for example, the battery data set 71 of FIG. 7a), wherein a first sub-model (for example, the first sub-model 715 of FIG. 7a) among the at least two or more sub-models outputs latent feature information (for example, the latent feature information 740 of FIG. 7a) by using, as an input, the cooling performance, the state information of the battery, the temperature of the battery, the battery location information, and the domain information, and a second sub-model (for example, the second sub-model 720 of FIG. 7a) among the at least two or more sub-models outputs the predicted state information of the battery by using, as an input, the cooling performance, the state information of the battery, the temperature of the battery, the battery location information, the prediction time point, and the latent feature information.

According to an embodiment, the final loss is determined based on loss items, and the loss items include at least one of a data fitting loss, a physics loss, a boundary condition loss, and an initial condition loss (for example, the data fitting loss 762, physics loss 764, boundary condition loss 766, and initial condition loss 768 of FIG. 7a), and each of the loss items may be determined by applying an adaptive weight.

According to an embodiment, the domain information comprises a size of a domain window, a number of domains, measurement time information within the domain window, and time difference information between the domain and a prediction time point, and the latent feature information may comprise a latent feature of a temperature, an SEI concentration, an anode concentration, a cathode concentration, and an electrolyte concentration at a specific location of the battery in a predetermined time domain.

According to an embodiment, the state information of the battery may include the gas composition of the battery and the internal pressure information of the battery.

In step S1130, the thermal runaway prediction apparatus may predict the possibility of thermal runaway based on the state information of the battery.

According to an embodiment, the state information of the battery at the specific time point may include the temperature, the concentration of SEI, the concentration of the anode, the concentration of the cathode, and the concentration of the electrolyte at the specific time point (for example, the predicted temperature 830a, predicted SEI concentration 830b, predicted anode concentration 830c, predicted cathode concentration 830d, and predicted electrolyte concentration 830e of FIG. 8).

According to an embodiment, the thermal runaway prediction apparatus may predict that thermal runaway will occur when the temperature of the battery increases at a predetermined slope or more, or predict that thermal runaway will occur when at least one of the concentration of the SEI, the concentration of the anode, the concentration of the cathode, and the concentration of the electrolyte becomes a predetermined value or more, or predict that thermal runaway will occur at a time point when the reaction of the anode concentration starts.

According to an embodiment, the thermal runaway prediction apparatus may output the state information of the battery by utilizing the trained artificial intelligence algorithm model when the temperature at the specific location of the battery exceeds a threshold.

According to an embodiment, the thermal runaway prediction apparatus may compare the possibility of thermal runaway with a threshold, and if the possibility of thermal runaway is equal to or greater than the threshold, may drive a system for controlling the thermal runaway, and the system for controlling the thermal runaway may include a cooling system and a phase transition system.

According to an embodiment of the present disclosure, it is possible to estimate the possibility of thermal runaway by predicting the state of a battery at a specific time using an artificial intelligence algorithm model trained based on virtual data.

According to an embodiment of the present disclosure, by utilizing a physics-informed artificial intelligence algorithm model for a thermal runaway prediction method that requires complex calculations, robust training is enabled with a small amount of data, thereby reducing the computational load for thermal runaway prediction, lowering complexity, and enabling faster result derivation.

The technical idea of the present disclosure has been described in detail with various embodiments as above, but the technical idea of the present disclosure is not limited to the above embodiments, and various modifications and changes are possible by those skilled in the art within the scope of the technical idea of the present disclosure.

What is claimed is:

1. A method performed by a thermal runaway prediction apparatus using artificial intelligence, the method comprising:
measuring a temperature at a specific location of a battery;
outputting state information of the battery at a specific time point from a pre-trained artificial intelligence algorithm model by using the temperature at the specific location of the battery and a cooling performance as an input; and
predicting a possibility of thermal runaway based on the state information of the battery.

2. The method of claim 1, wherein the specific location of the battery comprises at least one of a surface of the battery and an interior of the battery.

3. The method of claim 1, wherein:
the cooling performance comprises a performance of a cooling system applied to the battery, and
the performance of the cooling system comprises a temperature, a velocity, a specific heat, and a forced convection coefficient of a cooling fluid applied to the battery.

4. The method of claim 1, wherein the state information of the battery at the specific time point comprises a temperature of the battery, a concentration of a solid electrolyte interphase (SEI), a concentration of an anode, a concentration of a cathode, and a concentration of an electrolyte at the specific time point.

5. The method of claim 4, wherein the predicting of the possibility of thermal runaway comprises:
predicting the thermal runaway to occur when a temperature of the battery increases at a predetermined slope or more; or
predicting the thermal runaway to occur when at least one of a concentration of the SEI, a concentration of the anode, a concentration of the cathode, and a concentration of the electrolyte becomes a predetermined value or more; or
predicting the thermal runaway to occur at a time point when a reaction of the anode starts.

6. The method of claim 1, wherein:
the pre-trained artificial intelligence algorithm model is configured as a single artificial intelligence model or is configured with two or more sub-models,
the artificial intelligence model or the two or more sub-models each comprises a plurality of branch networks and a trunk network, and
the artificial intelligence model or the two or more sub-models are pre-trained by using, as an input, the cooling performance, state information of the battery included in a virtual data set, a temperature of the battery, location information of the battery, a prediction time point, and domain information.

7. The method of claim 6, wherein:
the virtual data set is generated through a multi-physics calculation model based on a virtual heating curve data set determined from a virtual scenario,
the virtual heating curve data set is determined by a combination of an initial temperature, an initial time, a heating target temperature, and a heating time, and
the multi-physics calculation model comprises a state estimation model, a thermodynamics model, a chemical reaction model, and a pressure estimation model related to an occurrence of thermal runaway of the battery.

8. The method of claim 6, wherein the pre-trained artificial intelligence algorithm model is trained by a method in which:
a first sub-model among the at least two or more sub-models outputs latent feature information by using, as an input, the cooling performance, the state information of the battery, the temperature of the battery, the location information of the battery, and the domain information,
a second sub-model among the at least two or more sub-models outputs predicted state information of the battery by using, as an input, the cooling performance, the state information of the battery, the temperature of the battery, the location information of the battery, the prediction time point, and the latent feature information, and
the training is performed based on a final loss determined based on the outputted predicted state information of the battery and the state information of the battery.

9. The method of claim 8, wherein:
the final loss is determined based on loss items,
the loss items comprise at least one of a data fitting loss, a physics loss, a boundary condition loss, and an initial condition loss, and
each of the loss items is determined by applying an adaptive weight.

10. The method of claim 8, wherein:
the domain information comprises a size of a domain window, a number of domains, measurement time information within the domain window, and time difference information between the domain and a prediction time point, and
the latent feature information comprises a latent feature of a temperature, a concentration of an SEI, a concentration of an anode, a concentration of a cathode, and a concentration of an electrolyte at a specific location of the battery in a predetermined time domain.

11. The method of claim 1, wherein the outputting of the state information of the battery comprises:
outputting the state information of the battery by utilizing the trained artificial intelligence algorithm model when the temperature at the specific location of the battery exceeds a threshold value.

12. The method of claim 11, wherein the state information of the battery comprises gas composition of the battery and internal pressure information of the battery.

13. The method of claim 1, further comprising:
comparing the possibility of thermal runaway with a threshold value; and
driving a system for controlling the thermal runaway when the possibility of thermal runaway is equal to or greater than the threshold value, and
wherein the system for controlling the thermal runaway comprises a cooling system and a phase transition system.

14. An electronic device comprising:
a memory;
a modem; and
a processor connected to the modem and the memory,
wherein the processor is configured to:
measure a temperature at a specific location of a battery,
output state information of the battery at a specific time point from a pre-trained artificial intelligence algorithm model by using the temperature at the specific location of the battery and a cooling performance as an input, and
predict a possibility of thermal runaway based on the state information of the battery.

15. A program stored in a medium for predicting thermal runaway through an artificial intelligence algorithm executable by a processor, the program configured to cause the processor to perform steps of:
measuring a temperature at a specific location of a battery;
outputting state information of the battery at a specific time point from a pre-trained artificial intelligence algorithm model by using the temperature at the specific location of the battery and a cooling performance as an input; and
predicting a possibility of thermal runaway based on the state information of the battery.
